(19) United States
(12) Patent Application Publication
(10) Pub. No.: US 2009/0108277 A1
(43) Pub. Date: Apr. 30, 2009

(54) PERIODICALLY STRUCTURED SUBSTRATE AND LIGHT EMITTING DEVICE INCLUDING THE SAME

(75) Inventors: Chih-Kuei HSU, Tainan Hsien (TW); Hai-Wen Hsu, Tainan Hsien (TW); Kuan-Jen Chung, Tainan Hsien (TW)

Correspondence Address: FOLEY AND LARDNER LLP;SUITE 500, 3000 K STREET NW, WASHINGTON, DC, 20007, US

(73) Assignee: Genesis Photonics Inc.

(21) Appl. No.: 11/926,267

(22) Filed: Oct. 29, 2007

(51) Int. Cl. G02B 5/02; H01L 33/00

(52) U.S. Cl. 257/98; 359/599; 257/E33.001

(57) ABSTRACT

A periodically structured substrate includes a slab and a periodic structure formed on the slab and including a plurality of spaced apart first surrounding elements and a plurality of spaced apart central elements. The first surrounding elements are periodically arranged in such a manner to form repeating polygonal patterns. Each of the central elements is disposed at a center of a respective one of the polygonal patterns. The periodic structure further includes a spacer medium that fills a space among the central element and the first surrounding elements of each of the polygonal patterns and that has a refractive index different from those of the central element and the first surrounding elements.

### BACKGROUND OF THE INVENTION

1. Field of the Invention

This invention relates to a periodically structured substrate and a light emitting device including the same, more particularly to a periodically structured substrate including a plurality surrounding elements periodically arranged into repeating polygonal patterns, and a plurality of central elements disposed respectively in centers of the polygonal patterns.

2. Description of the Related Art

U.S. Pat. No. 6,821,804 discloses a light emitting device including first and second spreader layers, an LED structure having an epitaxial layer and sandwiched between the first and second spreader layers, a substrate, and a plurality of light extraction elements (LEEs) formed in an array and disposed between the second spreader layer and the substrate. The LEEs provide reflections and refractions that can redirect trapped light into a direction that allows the light to escape from the light emitting device. Although the aforesaid light emitting device can improve the light extraction efficiency, the improvement is still limited due to a simple configuration of each of the LEEs.

In addition, conventional light emitting devices suffer from dislocation defects due to lattice mismatch between the substrate and the epitaxial layer formed thereon.

### SUMMARY OF THE INVENTION

Therefore, the object of the present invention is to provide a light emitting device including a periodically structured substrate that can provide better reflection, refraction and scattering of light passing therethrough and that can reduce the dislocation defects in the epitaxial layer as compared to the aforesaid conventional light emitting device.

According to this invention, there is provided a periodically structured substrate that comprises a slab and a periodic structure formed on the slab and including a plurality of spaced apart first surrounding elements and a plurality of spaced apart central elements. The first surrounding elements are periodically arranged in such a manner to form repeating polygonal patterns. Each of the central elements is disposed at a center of a respective one of the polygonal patterns. The periodic structure further includes a spacer medium that fills a space among the central element and the first surrounding elements of each of the polygonal patterns and that has a refractive index different from those of the central element and the first surrounding elements.

### BRIEF DESCRIPTION OF THE DRAWING

Other features and advantages of the present invention will become apparent in the following detailed description of the preferred embodiments of this invention, with reference to the accompanying drawings, in which:

FIG. 1 is a schematic view of the first preferred embodiment of a light emitting device according to this invention;

FIG. 2 is a perspective view to illustrate the configuration of a periodic structure of the first preferred embodiment;

FIG. 3 is a schematic view illustrating the configuration of a periodically structured substrate of the second preferred embodiment according to this invention;

FIG. 4 is a perspective view illustrating the configuration of a periodic structure of the third preferred embodiment according to this invention;

FIG. 5 is a fragmentary perspective view illustrating the configuration of a periodically structured substrate of the fourth preferred embodiment according to this invention;

FIG. 6 is a schematic view illustrating the configuration of a periodically structured substrate of the fifth preferred embodiment according to this invention;

FIG. 7 is a perspective view illustrating the configuration of a periodic structure of the periodically structured substrate of the fifth preferred embodiment;

FIG. 8 is a schematic view illustrating the configuration of a periodically structured substrate of the sixth preferred embodiment according to this invention;

FIG. 9 is a perspective view illustrating the configuration of a periodic structure of the seventh preferred embodiment according to this invention;

FIG. 10 is a fragmentary perspective view illustrating the configuration of a periodically structured substrate of the eighth preferred embodiment according to this invention;

FIG. 11 is a schematic view illustrating the configuration of a periodically structured substrate of the ninth preferred embodiment according to this invention; and

FIG. 12 is a fragmentary perspective view illustrating the configuration of the periodically structured substrate of the ninth preferred embodiment.

### DETAILED DESCRIPTION OF THE PREFERRED EMBODIMENTS

Before the present invention is described in greater detail with reference to the accompanying preferred embodiments, it should be noted herein that like elements are denoted by the same reference numerals throughout the disclosure.

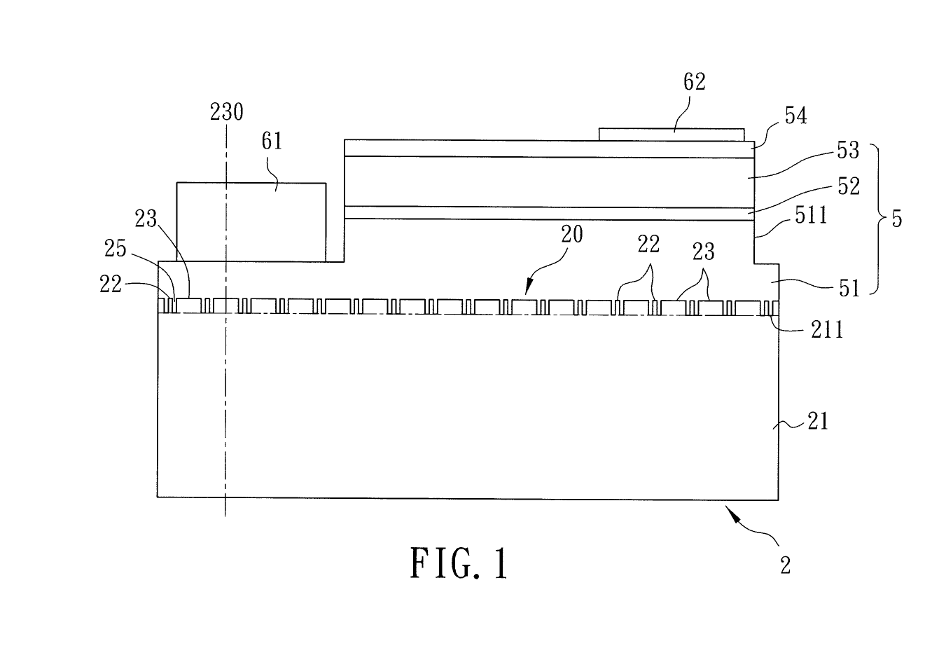

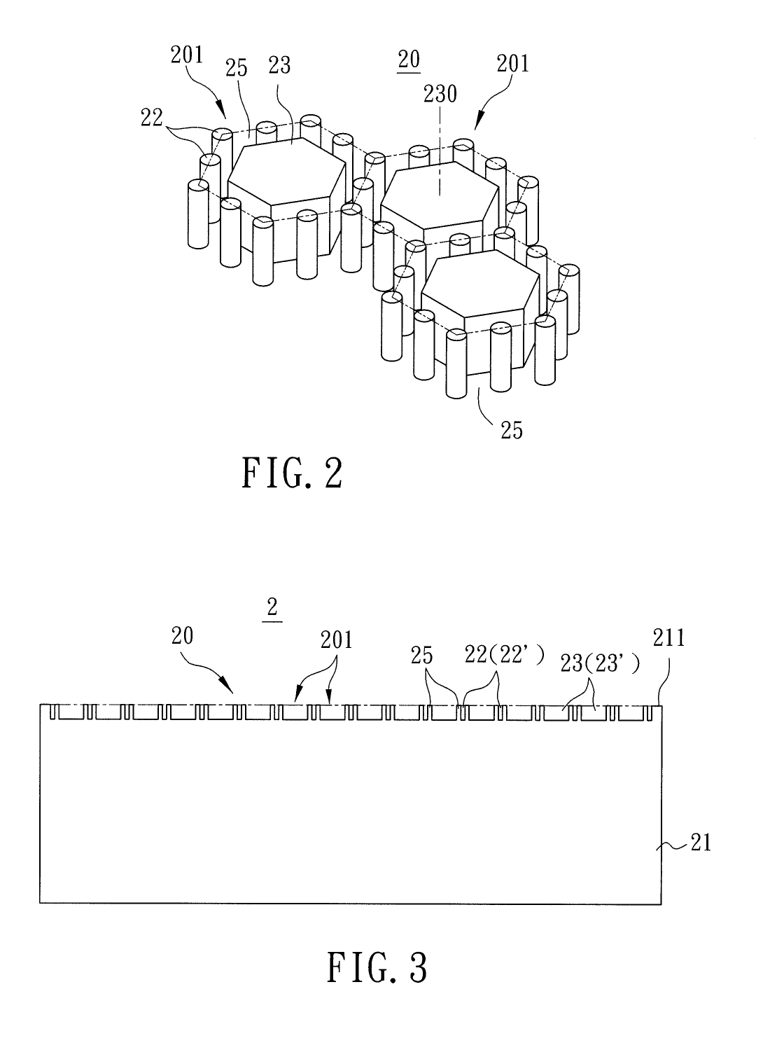

FIGS. 1 and 2 illustrate the first preferred embodiment of a light emitting device according to this invention. The light emitting device includes: a periodically structured substrate 2 having a slab 21 and a periodic structure 20 formed on the slab 21; an epitaxial structure 5 formed on the periodic structure 20 and including first and second cladding layers 51, 53 and an active layer 52 disposed between the first and second cladding layers 51, 53; a current spreading layer 54 (such an indium tin oxide (ITO) layer) formed on the second cladding layer 53; and first and second electrodes 61, 62 coupled electrically to the first and second cladding layers 51, 53.

The periodic structure 20 includes a plurality of spaced apart first surrounding elements 22 and a plurality of spaced apart central elements 23. The first surrounding elements 22 are periodically arranged in such a manner to form repeating polygonal patterns 201 that are interconnected. Each of the central elements 23 is disposed at a center of a respective one of the polygonal patterns 201, and extends along an axis 230 defined by a respective one of the polygonal patterns 201. The periodic structure 20 further includes a spacer medium 25 that fills a space among the central element 23 and the first surrounding elements 22 of each of the polygonal patterns 201 and that has a refractive index different from those of the central element 23 and the first surrounding elements 22.

In this embodiment, the slab 21 and the central and first surrounding elements 23, 22 of each of the polygonal patterns 201 are made from a material selected from the group consisting of sapphire, aluminum oxide, zinc carbide, zinc oxide, and gallium arsenide, and the spacer medium 25 is air.

Each of the first surrounding elements 22 of each of the polygonal patterns 201 is spaced apart from an adjacent one of the first surrounding elements 22 of the respective one of the polygonal patterns 201 by a distance equal to an integer multiple of a quarter-wavelength of a light passing therethrough.

In this embodiment, each of the polygonal patterns 201 is a hexagonal pattern. Each of the first surrounding elements 22 is cylindrical in shape or rod-like in shape, and has a radius ranging from 0.5-2 μm and a length relative to a surface 211 of the slab 21 ranging from 1-3 μm. The central element 23 of each of the polygonal patterns 201 is hexagonal in shape or hexagonal rod-like in shape, and has a length relative to the surface 211 of the slab 21 ranging from 1-3 μm, and six sides, each of which has a length ranging from 3-6 μm.

FIG. 3 illustrates the periodically structured substrate 2 of the second preferred embodiment of the light emitting device according to this invention. The second preferred embodiment differs from the previous embodiment in that the periodic structure 20 is formed with a plurality of surrounding holes 22′ that are filled with air, and a plurality of central holes 23′ that are filled with air, and that each of the surrounding holes 22′ defines a respective one of the first surrounding elements 22, and each of the central holes 23′ defines a respective one of the central elements 23. In this embodiment, each of the central and first surrounding elements 23, 22 has a depth or a length relative to the surface 211 of the slab 21 ranging from 1-3 μm. The slab 21 and the spacer medium 25 are made from a material selected from the group consisting of sapphire, aluminum oxide, zinc carbide, zinc oxide, and gallium arsenide.

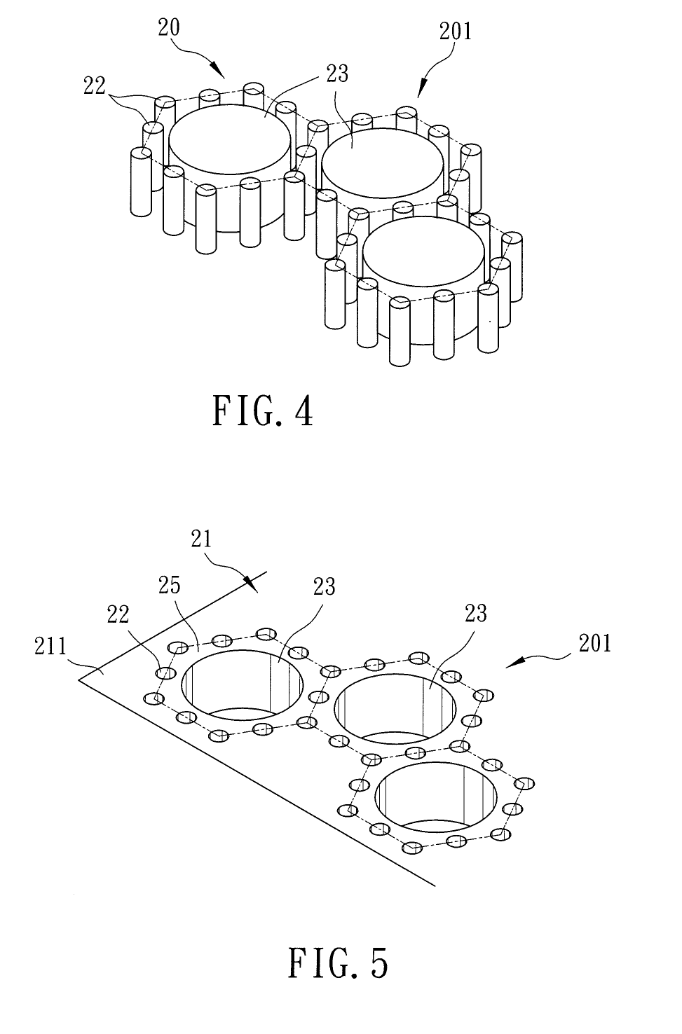

FIG. 4 illustrates the periodic structure 20 of the third preferred embodiment of the light emitting device according to this invention. The third preferred embodiment differs from the first embodiment in that each of the central elements 23 is cylindrical in shape and has a radius ranging from 1-6 μm.

FIG. 5 illustrates the periodic structure 20 of the fourth preferred embodiment of the light emitting device according to this invention. The fourth preferred embodiment differs from the second embodiment in that each of the central elements 23 is cylindrical in shape.

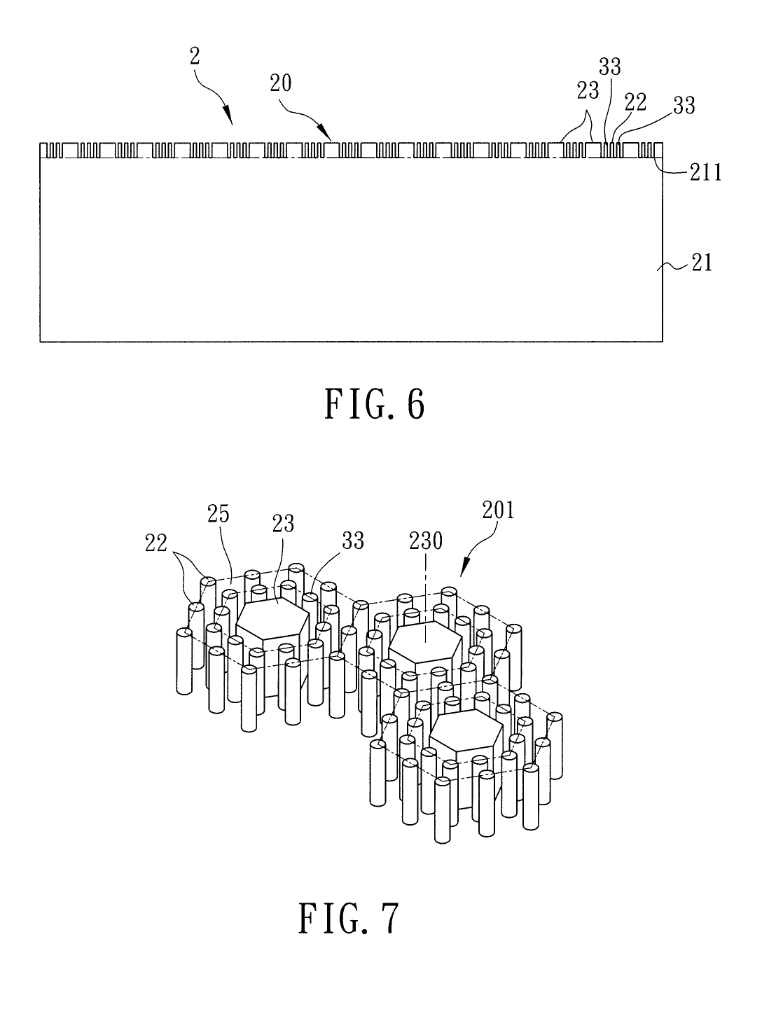

FIGS. 6 and 7 illustrate the fifth preferred embodiment of the light emitting device according to this invention. The fifth preferred embodiment differs from the first preferred embodiment in that the periodic structure 20 further includes a plurality of spaced apart second surrounding elements 33 disposed between the first surrounding elements 22 and the central element 23 of each of the polygonal patterns 201 and equiangularly disposed around the axis 230 of the respective one of the polygonal patterns 201. The spacer medium 25 further fills a space among the first and second surrounding elements 22, 33.

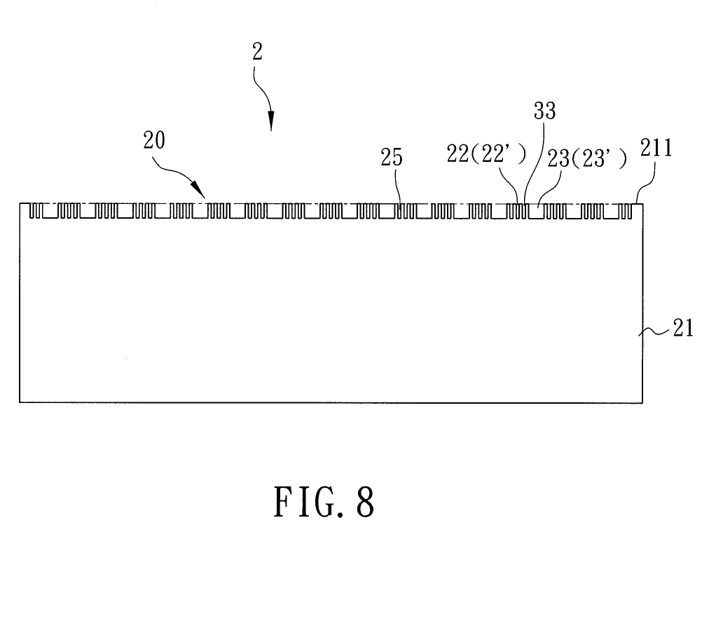

FIG. 8 illustrates the periodically structured substrate 2 of the sixth preferred embodiment of the light emitting device according to this invention. The sixth preferred embodiment differs from the fifth preferred embodiment in that the periodic structure 20 is formed with a plurality of first surrounding holes 22′ filled with air, a plurality of central holes 23′ filled with air, and a plurality of second surrounding holes 33′ filled with air and disposed between the first surrounding holes 22′ and the central holes 23′, and that each of the surrounding holes 22′ defines a respective one of the first surrounding elements 22, each of the central holes 23′ defines a respective one of the central elements 23, and each of the second surrounding holes 33′ defines a respective one of the second surrounding elements 33. In this embodiment, each of the first and second surrounding elements 22, 33 and the central elements 23 has a depth or a length relative to the surface 211 of the slab 21 ranging from 1-3 μm. The slab 21 and the spacer medium 25 are made from a material selected from the group consisting of sapphire, aluminum oxide, zinc carbide, zinc oxide, and gallium arsenide.

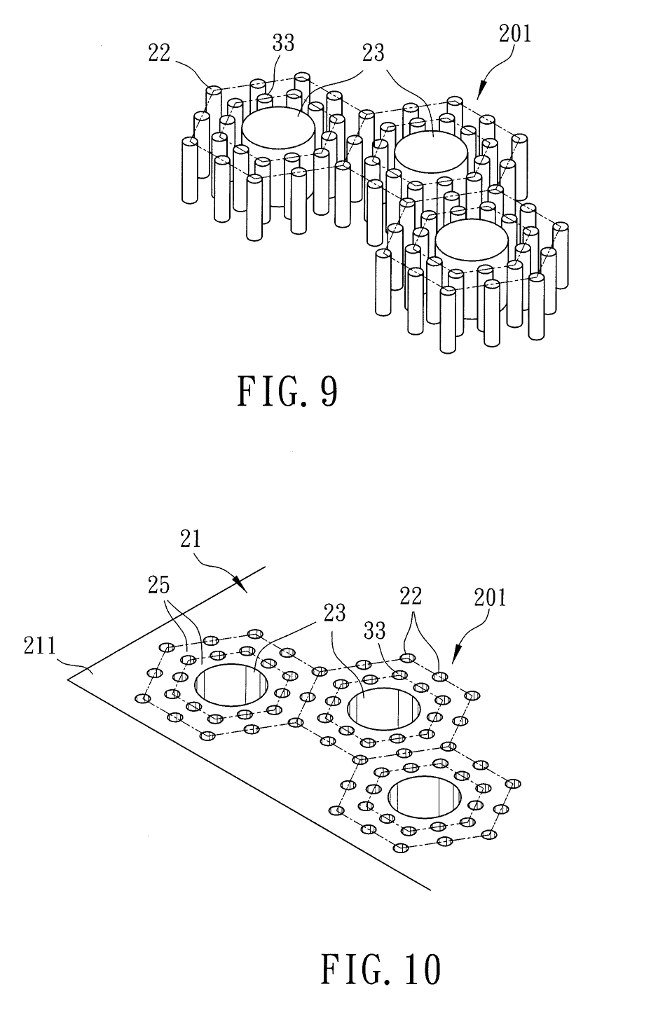

FIG. 9 illustrates the periodic structure 20 of the seventh preferred embodiment of the light emitting device according to this invention. The seventh preferred embodiment differs from the fifth preferred embodiment in that each of the central elements 23 is cylindrical in shape.

FIG. 10 illustrates the periodically structured substrate 2 of the eighth preferred embodiment of the light emitting device according to this invention. The eighth preferred embodiment differs from the sixth preferred embodiment in that each of the central elements 23 is cylindrical in shape.

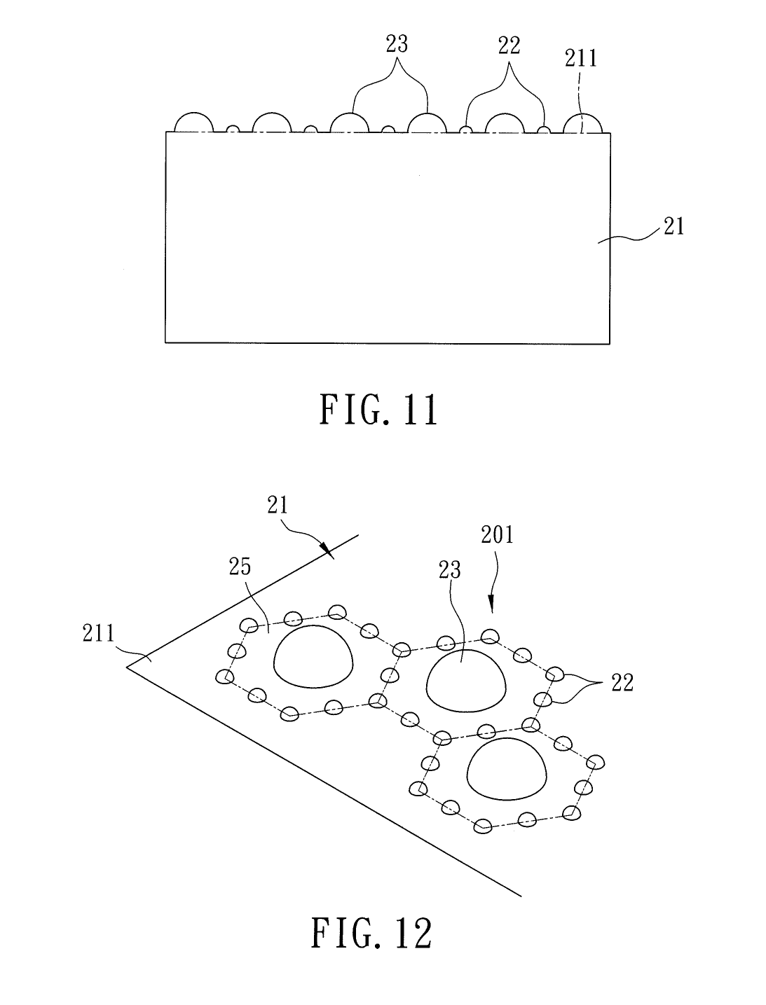

FIGS. 11 and 12 illustrate the ninth preferred embodiment of the light emitting device according to this invention. The ninth preferred embodiment differs from the first preferred embodiment in that each of the first surrounding elements 22 of each of the polygonal patterns 201 is hemi-ellipsoid in shape and has a primary axis with a half length ranging from 0.5-2 μm, and that the central element 23 of each of the polygonal patterns 201 is hemi-ellipsoid in shape and has a primary axis with a half length ranging from 1-4 μm. In this embodiment, each of the central and first surrounding elements 23, 22 has a height ranging from 0.3-4 μm relative to the surface 211 of the slab 21.

With the inclusion of the periodic structure 20 in the periodically structured substrate 2 of the light emitting device of this invention, the dislocation defects of the epitaxial structure 5 resulting from the lattice mismatch between the substrate 21 and the epitaxial structure 5 can be considerably reduced, and the reflection, refraction and scattering of light passing therethrough can also be significantly enhanced.

While the present invention has been described in connection with what are considered the most practical and preferred embodiments, it is understood that this invention is not limited to the disclosed embodiments but is intended to cover various arrangements included within the spirit and scope of the broadest interpretation and equivalent arrangements.

What is claimed is:

1. A periodically structured substrate comprising:
a slab; and
a periodic structure formed on said slab and including a plurality of spaced apart first surrounding elements and a plurality of spaced apart central elements, said first surrounding elements being periodically arranged in such a manner to form repeating polygonal patterns, each of said central elements being disposed at a center of a respective one of said polygonal patterns, said periodic structure further including a spacer medium that fills a space among said central element and said first surrounding elements of each of said polygonal patterns and that has a refractive index different from those of said central element and said first surrounding elements.

2. The periodically structured substrate of claim 1, wherein each of said first surrounding elements of each of said polygonal patterns is spaced apart from an adjacent one of said first surrounding elements of the respective one of said polygonal patterns by a distance equal to an integer multiple of a quarter-wavelength of a light passing therethrough.

3. The periodically structured substrate of claim 1, wherein each of said polygonal patterns is a hexagonal pattern.

4. The periodically structured substrate of claim 1, wherein each of said first surrounding elements is cylindrical in shape and has a radius ranging from 0.5-2 μm.

5. The periodically structured substrate of claim 4, wherein each of said central elements is hexagonal in shape and has six sides, each of which has a length ranging from 3-6 μm.

6. The periodically structured substrate of claim 4, wherein each of said central elements is cylindrical in shape and has a radius ranging from 1-6 μm.

7. The periodically structured substrate of claim 4, wherein each of said central and first surrounding elements has a length ranging from 1-3 μm.

8. The periodically structured substrate of claim 1, wherein each of said first surrounding elements is hemi-ellipsoid in shape and has a primary axis with a half length ranging from 0.5-2 μm.

9. The periodically structured substrate of claim 8, wherein each of said central elements is hemi-ellipsoid in shape and has a primary axis with a half length ranging from 1-4 μm.

10. The periodically structured substrate of claim 9, wherein each of said central and first surrounding elements has a height ranging from 0.3-4 μm.

11. The periodically structured substrate of claim 1, wherein said slab and said central and first surrounding elements are made from a material selected from the group consisting of sapphire, aluminum oxide, zinc carbide, zinc oxide, and gallium arsenide.

12. The periodically structured substrate of claim 11, wherein said spacer medium is air.

13. The periodically structured substrate of claim 1, wherein said periodic structure is formed with a plurality of surrounding holes that are filled with air, and a plurality of central holes that are filled with air, each of said surrounding holes defining a respective one of said first surrounding elements, each of said central holes defining a respective one of said central elements.

14. The periodically structured substrate of claim 13, wherein said slab and said spacer medium are made from a material selected from the group consisting of sapphire, aluminum oxide, zinc carbide, zinc oxide, and gallium arsenide.

15. The periodically structured substrate of claim 1, wherein said periodic structure further includes a plurality of second surrounding elements disposed between said first surrounding elements and said central element of each of said polygonal patterns.

16. A light emitting device comprising:
a periodically structured substrate including a slab and a periodic structure formed on said slab and including a plurality of spaced apart first surrounding elements and a plurality of spaced apart central elements, said first surrounding elements being periodically arranged in such a manner to form repeating polygonal patterns, each of said central elements being disposed at a center of a respective one of said polygonal patterns, said periodic structure further including a spacer medium that fills a space among said central element and said first surrounding elements of each of said polygonal patterns and that has a refractive index different from those of said central element and said first surrounding elements;
an epitaxial structure formed on said periodic structure and including first and second cladding layers and an active layer disposed between said first and second cladding layers; and
first and second electrodes coupled electrically to said first and second cladding layers.

17. The light emitting device of claim 16, wherein each of said first surrounding elements of each of said polygonal patterns is spaced apart from an adjacent one of said first surrounding elements of the respective one of said polygonal patterns by a distance equal to an integer multiple of a quarter-wavelength of a light passing therethrough.

18. The light emitting device of claim 16, wherein each of said polygonal patterns is a hexagonal pattern.

19. The light emitting device of claim 16, wherein said slab and said central and first surrounding elements are made from a material selected from the group consisting of sapphire, aluminum oxide, zinc carbide, zinc oxide, and gallium arsenide, and said spacer medium is air.

20. The light emitting device of claim 16, wherein said periodic structure is formed with a plurality of surrounding holes that are filled with air, and a plurality of central holes that are filled with air, each of said surrounding holes defining a respective one of said first surrounding elements, each of said central holes defining a respective one of said central elements, said slab and said spacer medium being made from a material selected from the group consisting of sapphire, aluminum oxide, zinc carbide, zinc oxide, and gallium arsenide.

21. The light emitting device of claim 16, wherein said periodic structure further includes a plurality of second surrounding elements disposed between said first surrounding elements and said central element of each of said polygonal patterns.
